(19) United States
(12) Patent Application Publication
(10) Pub. No.: US 2023/0417909 A1
(43) Pub. Date: Dec. 28, 2023

(54) LIGHT EMISSION DEVICE AND DISTANCE MEASUREMENT DEVICE

(71) Applicant: Panasonic Intellectual Property Management Co., Ltd., Osaka (JP)

(72) Inventors: Kiyoshi MORIMOTO, Osaka (JP); Hirotaka UENO, Osaka (JP)

(21) Appl. No.: 18/244,103

(22) Filed: Sep. 8, 2023

Related U.S. Application Data
(63) Continuation of application No. PCT/JP2022/006234, filed on Feb. 16, 2022.

(30) Foreign Application Priority Data
Mar. 11, 2021 (JP) 2021-038922

(51) Int. Cl. G01S 17/10; G01S 7/481; G01R 15/04; G01R 19/10

(52) U.S. Cl. CPC G01S 17/10; G01S 7/4814; G01R 15/04; G01R 19/10

(57) ABSTRACT

A light emission device includes: a laser light source; an electric storage element for supplying a drive current to the laser light source; a switch element connected in series to the laser light source; and a monitoring circuit configured to monitor temporal change in a voltage of the electric storage element.

### CROSS REFERENCE TO RELATED APPLICATION

This application is a continuation of International Application No. PCT/JP2022/006234 filed on Feb. 16, 2022, entitled “LIGHT EMISSION DEVICE AND DISTANCE MEASUREMENT DEVICE”, which claims priority under 35 U.S.C. Section 119 of Japanese Patent Application No. 2021-038922 filed on Mar. 11, 2021, entitled “LIGHT EMISSION DEVICE AND DISTANCE MEASUREMENT DEVICE”. The disclosures of the above applications are incorporated herein by reference.

### BACKGROUND OF THE INVENTION

### Field of the Invention

The present invention relates to a light emission device that emits pulsed light, and a distance measurement device that measures the distance to an object using the pulsed light emitted from the light emission device.

### Description of Related Art

To date, a distance measurement device that measures the distance to an object using pulsed laser light whose intensity changes in a pulsed manner has been known. In this type of distance measurement device, for example, the distance to an object is measured on the basis of the time difference between the timing when laser light is emitted and the timing when reflected light, from the object, of the laser light is received. Japanese Laid-Open Patent Publication No. H07-229967 describes this type of distance measurement device.

When pulsed laser light is emitted as described above, a laser light source is controlled such that the amount of laser light per pulse satisfies the eye-safety criterion. However, if an abnormality occurs in a control circuit for the laser light source, this control can no longer be performed properly.

Japanese Laid-Open Patent Publication No. 2002-299754 describes a configuration for suppressing abnormal light emission of a laser diode. In this configuration, a voltage monitoring circuit and a laser diode power supply opening/closing circuit are added to a laser diode drive circuit, and occurrence of abnormal light emission of the laser diode is suppressed by shifting the time to turn on/off a power supply and the ON/OFF timing of the laser diode power supply opening/closing circuit from each other.

In the configuration of Japanese Laid-Open Patent Publication No. 2002-299754, it is possible to suppress abnormal light emission of the laser light source when the power supply is turned on and when the power supply is turned off, but it is difficult to deal with abnormalities that occur during operation of the laser light source.

### SUMMARY OF THE INVENTION

A first aspect of the present invention is directed to a light emission device. The light emission device according to this aspect includes: a laser light source; an electric storage element for supplying a drive current to the laser light source; a switch element connected in series to the laser light source; and a monitoring circuit configured to monitor temporal change in a voltage of the electric storage element.

The light emission device according to this aspect includes the monitoring circuit configured to monitor temporal change in a voltage of the electric storage element and thus can detect a failure of the switch element during operation of the laser light source. That is, when a failure such as a short circuit occurs in the switch element, a voltage waveform (temporal change in the voltage) of the electric storage element generated by discharge of the electric storage element changes from the state during normal operation. Therefore, during operation of the laser light source, by monitoring temporal change in the voltage of the electric storage element by the monitoring circuit, a failure of the switch element can be detected at any time. Accordingly, an abnormality of the light emission device based on a failure of the switch element can be detected in real time.

A second aspect of the present invention is directed to a distance measurement device. The distance measurement device according to this aspect includes: the light emission device according to the first aspect; a projection optical system configured to project pulsed light emitted from the light emission device, to a target region; and a light receiver configured to receive reflected light, from an object, of the pulsed light.

Since the distance measurement device according to this aspect includes the light emission device according to the first aspect, a failure of the switch element can be detected at any time during operation of the laser light source, and control for suppressing an abnormality of light emission of the laser light source can be performed on the basis of the detection result. Therefore, the reliability of the distance measurement device can be increased.

The effects and the significance of the present invention will be further clarified by the description of the embodiment below. However, the embodiment below is merely an example for implementing the present invention. The present invention is not limited to the description of the embodiment below in any way.

### BRIEF DESCRIPTION OF THE DRAWINGS

FIG. 1 is a block diagram showing a configuration of a distance measurement device according to an embodiment;

FIG. 2 is a circuit diagram showing a configuration of a light emission device according to the embodiment;

FIG. 3A to FIG. 3D are respectively time charts showing the simulation results of the voltage of an input part of a switch element, a drive current flowing through a laser light source, the voltage at a connection portion between an electric storage element and the laser light source, and a monitoring signal during normal operation according to the embodiment;

FIG. 4A to FIG. 4D are respectively time charts showing dashed line ranges in FIG. 3A to FIG. 3D with an extended time axis;

FIG. 5A to FIG. 5D are respectively time charts showing the simulation results of the voltage of the input part of the switch element, a drive current flowing through the laser light source, the voltage at the connection portion between the electric storage element and the laser light source, and a monitoring signal when a failure occurs in the switch element according to the embodiment;

FIG. 6 is a diagram showing a configuration of a circuitry for controlling drive of the laser light source on the basis of a monitoring signal according to the embodiment;

FIG. 7A is a flowchart showing a process of failure detection based on a monitoring signal according to the embodiment;

FIG. 7B is a flowchart showing another process of failure detection based on a monitoring signal according to the embodiment;

FIG. 8 is a diagram showing a configuration of a circuitry for controlling drive of a laser light source on the basis of a monitoring signal according to a modification; and

FIG. 9 is a circuit diagram showing a configuration of a light emission device according to another modification.

It should be noted that the drawings are solely for description and do not limit the scope of the present invention by any degree.

### DETAILED DESCRIPTION

Hereinafter, an embodiment of the present invention will be described with reference to the drawings.

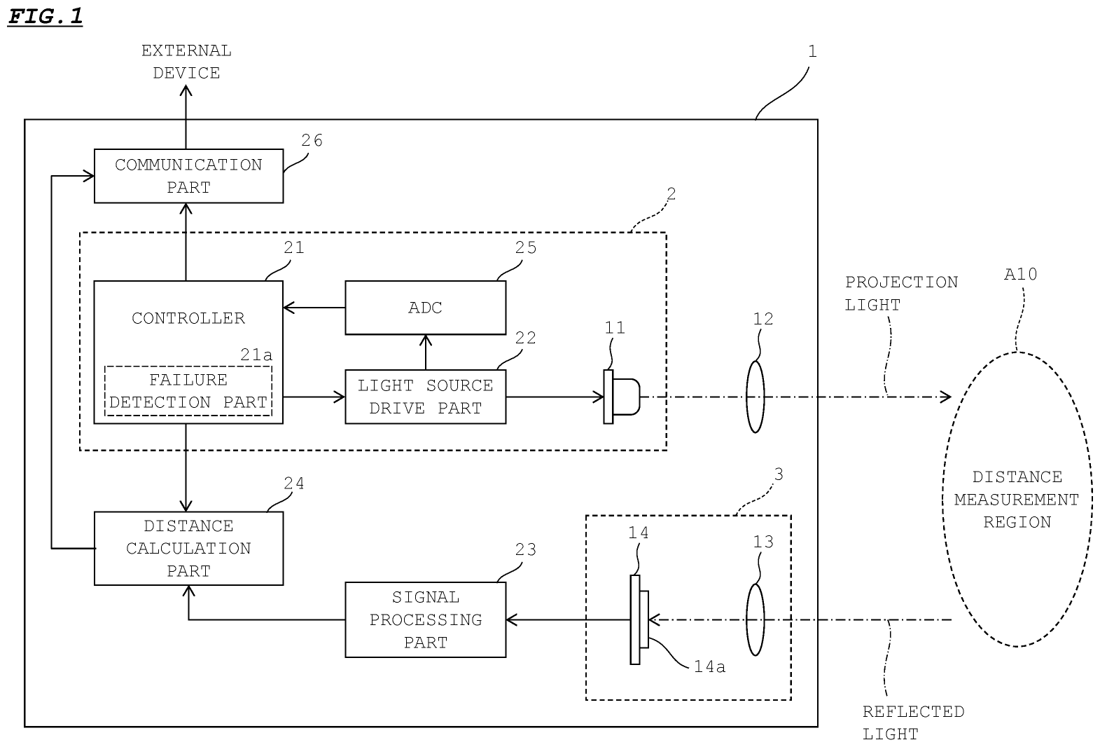

FIG. 1 is a block diagram showing a configuration of a distance measurement device 1 according to the embodiment. FIG. 1 shows a so-called flash type distance measurement device 1.

The distance measurement device 1 includes a laser light source 11, a projection optical system 12, a light-receiving optical system 13, and an imaging element 14 as components of an optical system.

The laser light source 11 is composed of a laser diode, for example, and emits laser light (projection light) having a predetermined wavelength. In the case where the distance measurement device 1 is installed in a vehicle, the emission wavelength of the laser light source 11 is set in the infrared wavelength band (e.g., 905 nm). The emission wavelength of the laser light source 11 can be changed as appropriate according to the usage of the distance measurement device 1. The laser light source 11 may be composed of a plurality of laser diodes. Alternatively, the laser light source 11 may be composed of another laser emitter other than laser diodes.

The projection optical system 12 guides the projection light emitted from the laser light source 11, to a distance measurement region A10 at a predetermined spread angle. The projection optical system 12 projects projection light with a uniform intensity distribution to the distance measurement region A10. The projection optical system 12 may be composed of a single lens or may include a plurality of lenses. The projection optical system 12 may also include a concave mirror or the like.

The light-receiving optical system 13 condenses reflected light of the laser light reflected by an object existing in the distance measurement region A10, onto a light-receiving surface 14a of the imaging element 14. The light-receiving optical system 13 may be composed of a single lens or may include a plurality of lenses. The light-receiving optical system 13 may also include a concave mirror or the like.

The imaging element 14 receives the reflected light by a plurality of pixels arranged on the light-receiving surface 14a, and outputs a detection signal corresponding to the intensity of the reflected light received. A large number of pixels are arranged in a matrix on the light-receiving surface 14a. In each pixel, for example, an avalanche photodiode is placed. Another light detection element may be placed in each pixel.

A filter that transmits the wavelength band of the projection light and blocks light in the other wavelength bands may be placed between the light-receiving optical system 13 and the imaging element 14. Accordingly, unnecessary light having wavelengths different from that of the projection light can be inhibited from being incident on the light-receiving surface 14a of the imaging element 14. In addition, in the case where the laser light source 11 emits infrared light, the imaging element 14 may have detection sensitivity only in the infrared wavelength band. Accordingly, detection of visible light, which is unnecessary light, by the imaging element 14 can be inhibited.

The distance measurement device 1 includes a controller 21, a light source drive part 22, a signal processing part 23, a distance calculation part 24, an A/D converter (ADC) 25, and a communication part 26 as components of a circuitry.

The controller 21 includes an arithmetic processing circuit and a memory, and is composed of, for example, an FPGA, an MPU, a ROM, a RAM, etc. The controller 21 outputs a control signal to the light source drive part 22 to control the laser light source 11 via the light source drive part 22. The light source drive part 22 causes the laser light source 11 to emit pulsed light at a predetermined intensity and pulse width in response to the control signal. The controller 21 also outputs the control signal outputted to the light source drive part 22, to the distance calculation part 24 at the same timing as the output to the light source drive part 22.

The signal processing part 23 performs amplification and noise removal on the detection signal of each pixel outputted from the imaging element 14, and outputs the processed detection signal to the distance calculation part 24.

The distance calculation part 24 is a circuit that includes an arithmetic processing circuit and a memory and performs calculation of a distance. The distance calculation part 24 calculates the distance to a target object in the distance measurement region A10 for each pixel on the basis of the timing when the control signal for pulsed light emission is received from the controller 21 and the timing when the detection signal of each pixel of the imaging element 14 is received from the signal processing part 23. The distance calculation part 24 generates distance image data for one screen (one frame) in which the distance calculated for each pixel is mapped to the position of each pixel, and outputs the generated distance image data to an external device via the communication part 26. For example, in the case where the distance measurement device 1 is installed in a vehicle, the distance image data is transmitted to a control unit on the vehicle side.

The ADC 25 converts a monitoring signal described later into a digital signal and transmits the digital signal to the controller 21. The communication part 26 communicates with the external device in accordance with the control from the controller 21.

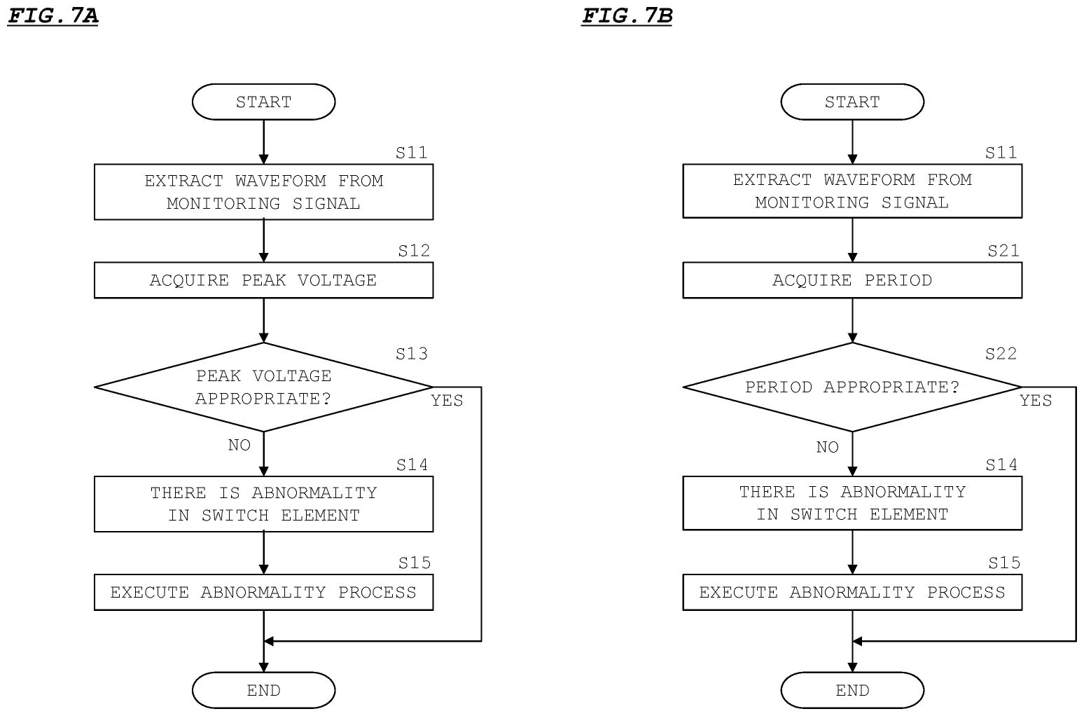

The controller 21 detects a failure of the light source drive part 22 on the basis of the monitoring signal received via the ADC 25. The function of a failure detection part 21a is given to the controller 21 by a program stored in the controller 21. By the function of the failure detection part 21a, the controller 21 performs a process such as detecting a failure of the light source drive part 22 and stopping the operation of the light source drive part 22 in accordance with the detection result. The process of the controller 21 by the function of the failure detection part 21a will be described with reference to FIG. 7A and FIG. 7B later.

In the configuration in FIG. 1, the laser light source 11, the light source drive part 22, the controller 21, and the ADC 25 constitute a light emission device 2. Here, the controller 21 controls the distance measurement device 1 as well as the light emission device 2. Also, the light-receiving optical system 13 and the imaging element 14 constitute a light receiver 3.

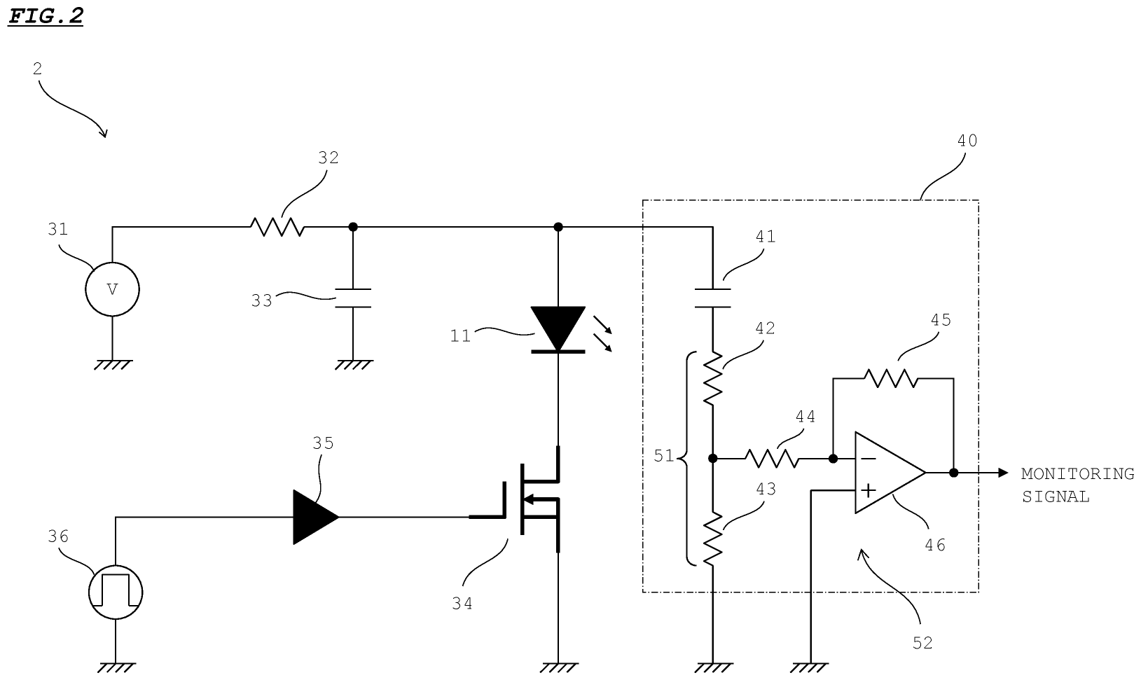

FIG. 2 is a circuit diagram showing a configuration of the light emission device 2 according to the embodiment. In FIG. 2, the controller 21 is not shown.

In addition to the laser light source 11 shown in FIG. 1, the light emission device 2 includes a DC power supply 31, a resistor 32, an electric storage element 33, a switch element 34, a driver 35, a pulse generation circuit 36, and a monitoring circuit 40 as components of the light source drive part 22.

The electric storage element 33 is composed of a capacitor and is connected to the DC power supply 31 via the resistor 32. The electric storage element 33 may be composed of a single capacitor or may be composed of a plurality of capacitors connected in parallel. Electric charge is accumulated in the electric storage element 33 according to the time constant of a circuit including the resistor 32 and the electric storage element 33. The electric storage element 33 discharges in response to the switch element 34 being made conductive, and supplies a drive current to the laser light source 11.

As described above, the laser light source 11 is a laser diode. The laser light source 11 emits laser light when the drive current is supplied from the electric storage element 33 thereto. A plurality of laser light sources 11 may be connected in parallel or connected in series between the electric storage element 33 and the switch element 34 to form a light source.

The switch element 34 is switched between a conductive state and a non-conductive state in response to a signal from the driver 35. The switch element 34 is, for example, a field effect transistor (FET). The switch element 34 may be composed of another switch element that is switched between a conductive state and a non-conductive state in response to a signal from the driver 35.

The switch element 34 switches the laser light source 11 between a light-emitting state and a non-light-emitting state according to the signal from the driver 35. That is, when the switch element 34 is brought into a conductive state, the drive current is supplied from the electric storage element 33 to the laser light source 11, and the laser light source 11 emits light. When the switch element 34 is brought into a non-conductive state, the supply of the drive current to the laser light source 11 is blocked, and the laser light source 11 is turned off.

The driver 35 drives the switch element 34 in response to the pulse signal inputted from the pulse generation circuit 36. The pulse generation circuit 36 outputs a pulse signal having a predetermined time width in response to receiving the control signal for pulsed light emission from the controller 21. The driver 35 sets the switch element 34 to a conductive state during a period corresponding to the time width of the pulse signal. The pulse generation circuit 36 may be incorporated in the controller 21.

In the case where the switch element 34 is a FET, the driver 35 supplies a drive signal to the gate of the FET during a period when the pulse signal rises. Accordingly, during the period corresponding to the pulse signal, the switch element 34 is brought into a conductive state, and the drive current is supplied to the laser light source 11. Thus, the laser light source 11 emits pulsed light.

The monitoring circuit 40 monitors temporal change in the voltage of the electric storage element 33 and outputs a monitoring signal corresponding to the temporal change. The monitoring circuit 40 includes a capacitor 41, resistors 42 to 45, and a differential circuit 46.

The capacitor 41 is for AC coupling the electric storage element 33 and the monitoring circuit 40. The capacitor 41 inhibits the current from the electric storage element 33 from flowing to the monitoring circuit 40 when the switch element 34 is set to a conductive state. Accordingly, the current from the electric storage element 33 can be caused to properly flow to a main circuitry on the laser light source 11 side, thereby allowing the laser light source 11 to properly emit pulsed light.

The resistors 42 and 43 constitute a voltage-dividing resistor 51 for generating a monitoring signal. When a temporal change occurs in the voltage of the electric storage element 33, a voltage is generated between the capacitor 41 and a ground in response to the temporal change. This voltage is a potential where the capacitance 41 side becomes zero potential and the ground side becomes negative potential. The resistors 42 and 43 divide this voltage having a negative polarity. Therefore, a voltage generated at a connection portion between the resistors 42 and 43 also has a negative polarity.

The resistors 44 and 45 and the differential circuit 46 constitute a well-known polarity inversion circuit 52. The polarity inversion circuit 52 inverts the polarity of the voltage divided by the voltage-dividing resistor 51 (resistors 42 and 43). As described above, when a temporal change in the voltage of the electric storage element 33 occurs, a voltage generated at the connection portion between the resistors 42 and 43 has a negative polarity. The polarity inversion circuit 52 inverts the polarity of this voltage to generate a monitoring signal having a positive polarity.

The resistance values of the resistors 42 and 43 are set such that the voltage of the monitoring signal is at a level that does not interfere with the circuit on the subsequent stage side. For example, the resistance values of the resistors 42 and 43 are set such that the peak voltage of the monitoring signal outputted from the monitoring circuit 40 when the switch element 34 is made normally conductive during pulsed light emission is set to the operating voltage of the controller 21 (CPU) (e.g., 3.3 V).

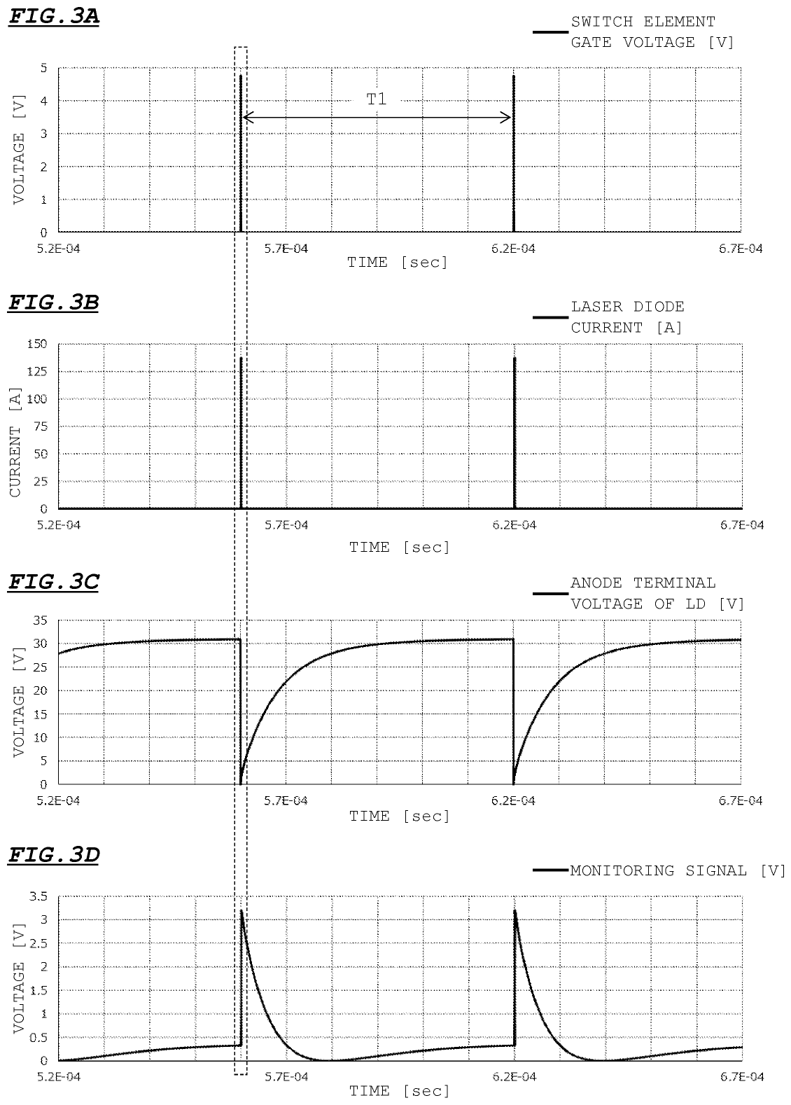

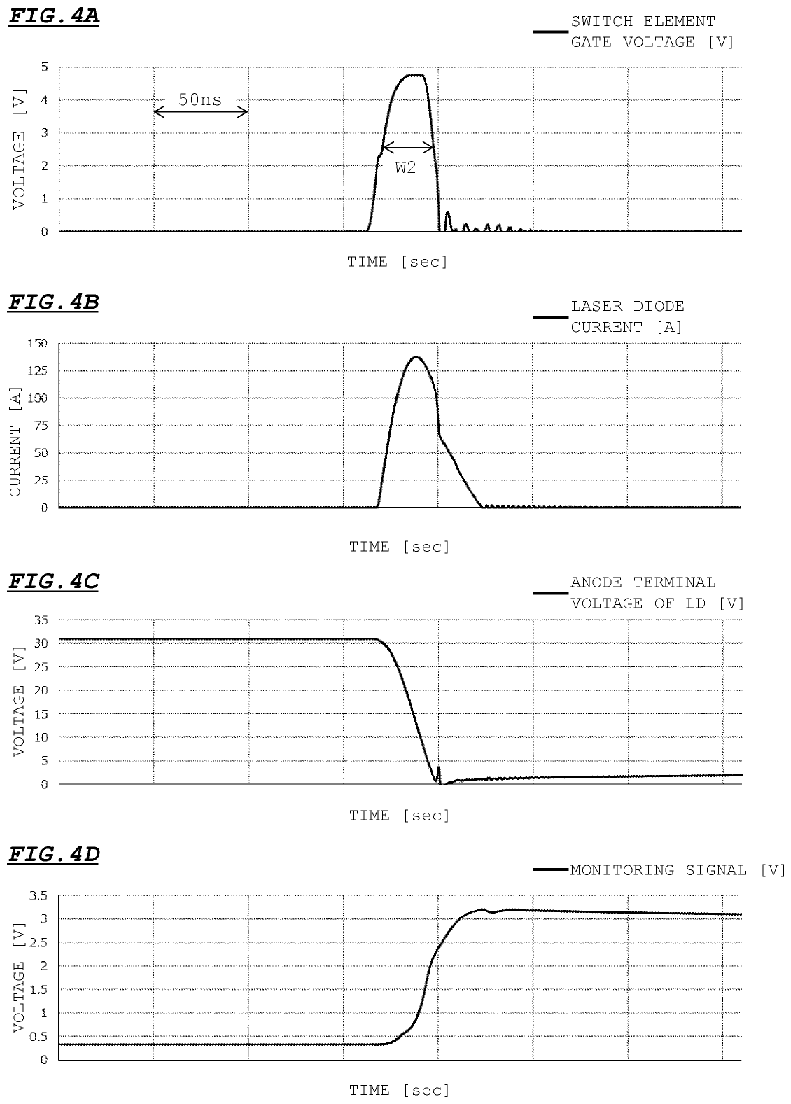

FIG. 3A to FIG. 3D are respectively time charts showing the simulation results of the voltage of an input part (gate) of the switch element 34, a drive current flowing through the laser light source 11, the voltage at a connection portion between the electric storage element 33 and the laser light source 11 (anode terminal of the laser light source 11), and a monitoring signal during normal operation. FIG. 4A to FIG. 4D are respectively time charts showing dashed line ranges in FIG. 3A to FIG. 3D with an extended time axis.

In this simulation, a period T1 of pulsed light emission shown in FIG. 3A is set to 60 ρsec. A time width W2 of a control pulse (gate signal) shown in FIG. 4A is set to 30 nsec. The resistor 32 in FIG. 2 is set to 80Ω, and the resistors 42 and 43 are set to 1 kΩ and 120Ω, respectively. The capacitor 41 in FIG. 2 is set to 10 nF, and each of the resistors 44 and 45 is set to 1 kΩ.

As shown in FIG. 3A, a pulsed drive signal is inputted to the input part (gate) of the switch element 34 in the period T1 of pulsed light emission. Here, the peak voltage of the drive signal is set to around 5 V. As a result of the input of each drive signal, the switch element 34 is made conductive during the pulse period of the drive signal, and the electric charge accumulated in the electric storage element 33 is discharged to the laser light source 11. Accordingly, as shown in FIG. 3B, a pulsed drive current flows through the laser light source 11.

When the electric charge in the electric storage element 33 is discharged as described above, the voltage of the electric storage element 33 sharply falls during the pulse period of the drive signal as shown in FIG. 3C. Then, when the switch element 34 turns to a non-conductive state due to the end of the drive voltage, the voltage of the electric storage element 33 converges to the power supply voltage of the DC power supply 31 with a time constant determined by the capacitance of the electric storage element 33 and the resistance value of the resistor 32, as electricity is stored in the electric storage element 33.

As shown in FIG. 3D, the monitoring signal of the monitoring circuit 40 changes in response to such temporal change in the voltage of the electric storage element 33 due to the discharge and the charge. As described above, the peak voltage of the monitoring signal is set to 3.3 V, which is the operating voltage of the controller 21 (CPU), by the resistance values of the resistors 42 and 43.

As shown in FIG. 4A, in the case where the above simulation conditions are applied, the time width W2 of the control pulse of the switch element 34 is 30 nsec, which is a specified value, even when the monitoring circuit 40 is connected. As shown in FIG. 4B, the drive current of the laser light source 11 also has an appropriate pulse waveform. Therefore, it can be said that the operation of the main circuit on the laser light source 11 side is hardly interfered with even when the monitoring circuit 40 is connected as described above.

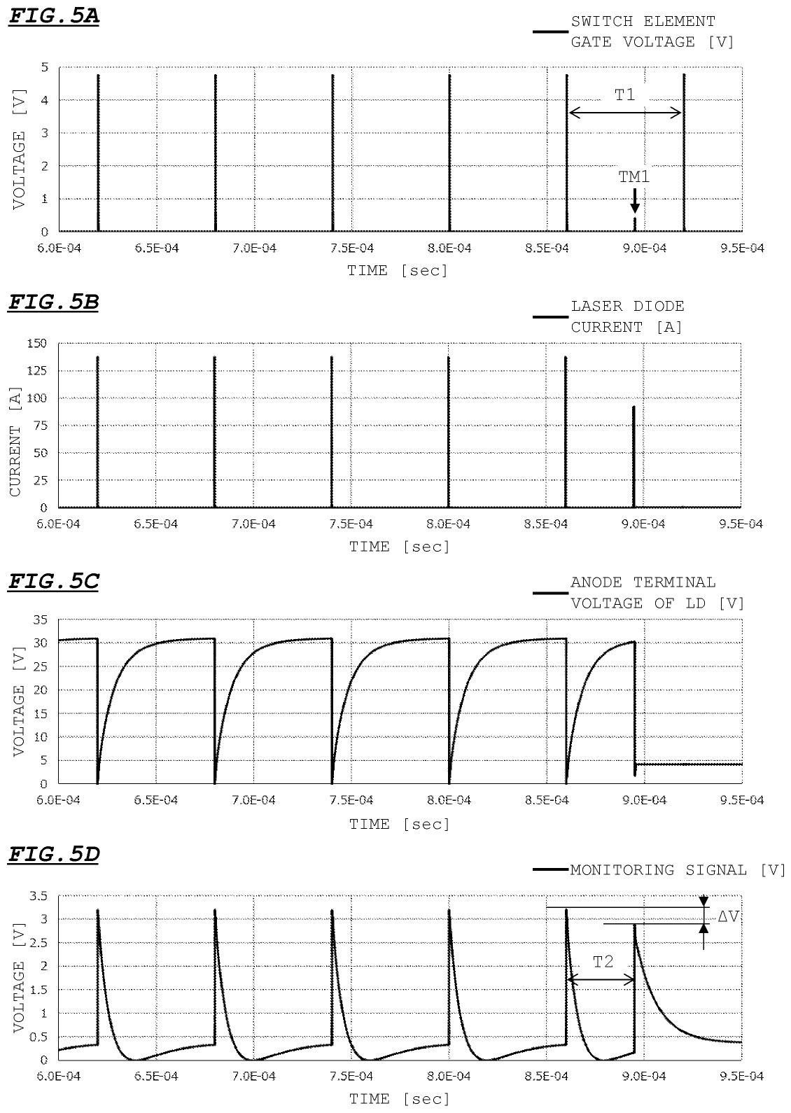

FIG. 5A to FIG. 5D are respectively time charts showing the simulation results of the voltage of the input part (gate) of the switch element 34, a drive current flowing through the laser light source 11, the voltage at the connection portion between the electric storage element 33 and the laser light source 11 (anode terminal of the laser light source 11), and a monitoring signal when a failure occurs in the switch element 34.

The conditions for this simulation are the same as in the case of FIG. 3A to FIG. 3D. In this simulation, it is assumed that a short circuit occurs in the switch element 34 at timing TM1 in FIG. 5A.

As shown in FIG. 5B, at the timing TM1 when a short circuit occurs in the switch element 34, the electric charge accumulated in the electric storage element 33 is discharged, and a drive current flows through the laser light source 11. In addition, after that, due to the short circuit of the switch element 34, no electric charge is accumulated in the electric storage element 33, and thus after the timing TM1, as shown in FIG. 5B, no pulsed drive current flows through the laser light source 11 due to the drive signal (gate voltage: see FIG. 5A) inputted to the input part of the switch element 34.

As shown in FIG. 5C, at the timing TM1 when a short circuit occurs in the switch element 34, the voltage of the electric storage element 33 sharply falls to a predetermined voltage level due to the discharge of the electric storage element 33 caused by this short circuit. Then, the voltage of the electric storage element 33 is maintained at the voltage after the fall. The voltage of the electric storage element 33 after the fall is a voltage value based on the resistance value of the resistor 32 and the resistance values of the laser light source 11 and the switch element 34 in the short circuit state.

When the voltage of the electric storage element 33 changes due to the short circuit of the switch element 34 as described above, a waveform corresponding to the temporal change in the voltage is generated in the monitoring signal of the monitoring circuit 40 as shown in FIG. 5D. The peak voltage of the waveform at this time is smaller than the peak voltage of the waveform during normal operation by a predetermined difference ΔV on the basis of the voltage fall of the switch element 34 due to the short circuit. In addition, if a short circuit occurs during the period T1 of pulsed light emission, a period T2 between the waveform generated in the monitoring signal due to the short circuit and the waveform during normal operation immediately before the short circuit is shorter than the period T1 of pulsed light emission. Therefore, the presence/absence of a failure in the switch element 34 can be monitored on the basis of the state of the pulsed waveform generated in the monitoring signal.

As described with reference to FIG. 3C, after discharge is made by the conduction of the switch element 34, the voltage of the electric storage element 33 converges to the power supply voltage of the DC power supply 31 with the time constant determined by the capacitance of the electric storage element 33 and the resistance value of the resistor 32, as electricity is stored in the electric storage element 33. Here, the resistance value of the resistor 32 is set such that the voltage of the electric storage element 33 returns to the drive voltage of the DC power supply 31 within the period T1 of pulsed light emission. On the other hand, as the resistance value of the resistor 32 is higher, the current flowing in the circuit when the switch element 34 is short-circuited can be smaller, so that light emission of the laser light source 11 can be suppressed. Therefore, from the viewpoint of suppressing abnormal light emission of the laser light source 11 when the switch element 34 is short-circuited, it can be said that it is preferable to set the resistance value of the resistor 32 to be as large as possible within the range where the voltage of the electric storage element 33 returns to the drive voltage of the DC power supply 31 within the period T1 of pulsed light emission.

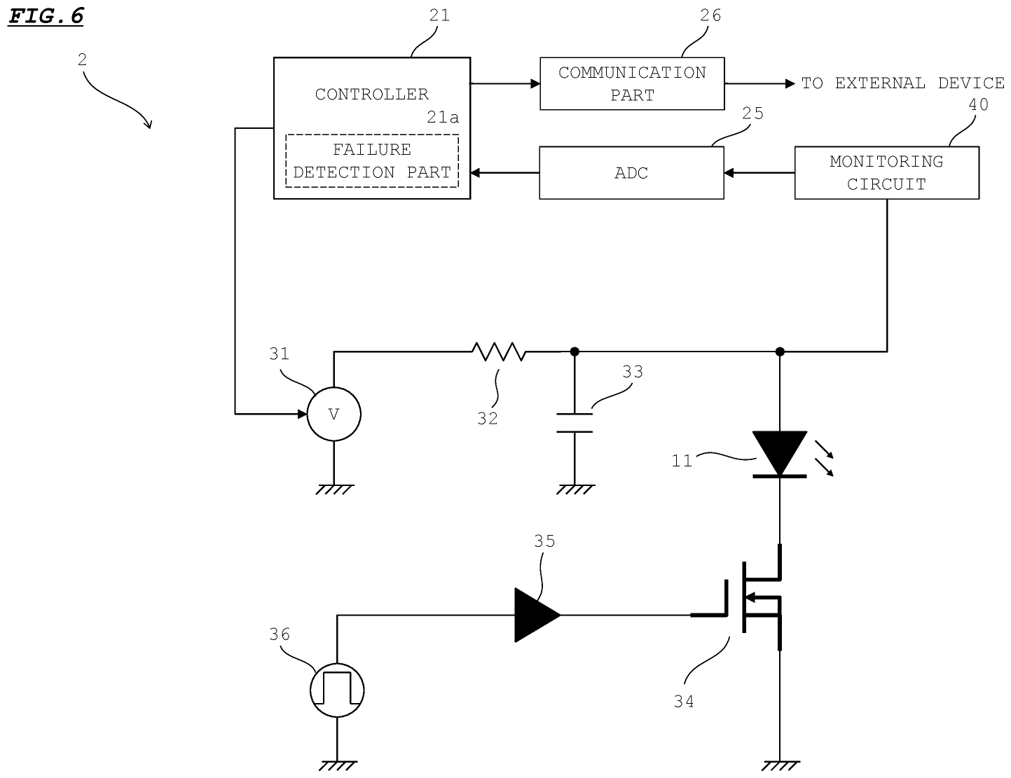

FIG. 6 is a diagram showing a configuration of a circuitry for controlling drive of the laser light source 11 on the basis of a monitoring signal. In FIG. 6, the communication part 26 is also shown in addition to the configuration of the light emission device 2.

The monitoring signal generated by the monitoring circuit 40 is constantly converted into digital data by the ADC and then inputted to the controller 21. The controller 21 detects the presence/absence of a failure of the switch element 34 on the basis of the monitoring signal by the function of the failure detection part 21a. Here, as described above, the presence/absence of a failure of the switch element 34 is detected on the basis of the pulsed waveform generated in the monitoring signal. When the controller 21 detects that a failure has occurred in the switch element 34, the controller 21 stops the DC power supply 31 to stop driving the laser light source 11. In addition, at the same time, the controller 21 notifies the external device via the communication part 26 that a failure has occurred in the switch element 34.

FIG. 7A is a flowchart showing a process of failure detection based on a monitoring signal. As described above, the controller 21 performs this process by the function of the failure detection part 21a.

First, the controller 21 extracts a waveform that changes beyond a predetermined noise level, from the monitoring signal inputted from the monitoring circuit 40 (S11). Next, the controller 21 acquires the peak voltage of the extracted waveform (S12) and determines whether or not the acquired peak voltage is appropriate (S13).

Specifically, the controller 21 compares a reference voltage stored therein in advance with the peak voltage acquired in step S12, and determines whether or not the peak voltage is appropriate. Here, the reference voltage is set to a voltage corresponding to the peak voltage of a waveform generated by the drive of the switch element 34 when the switch element 34 is normal.

When the a difference ΔV between the peak voltage acquired in step S12 and the reference voltage is equal to or less than a predetermined threshold, the controller 21 determines that the peak voltage is appropriate. On the other hand, when the difference ΔV between the peak voltage and the reference voltage exceeds the threshold, the controller 21 determines that the peak voltage is not appropriate. Here, the threshold is set to a value that is larger than the range where the peak of the waveform of the monitoring signal can vary when the switch element 34 is normal and that allows a failure of the switch element 34 to be detected properly.

When the peak voltage acquired in step S12 is appropriate (S13: YES), the controller 21 determines that no abnormality has occurred in the switch element 34, and ends the process. In this case, the controller 21 executes the process from step S11 again, and executes the same process as above for the next waveform of the monitoring signal.

On the other hand, when the peak voltage acquired in step S12 is not appropriate (S13: NO), the controller 21 determines that an abnormality has occurred in the switch element 34 (S14), and executes a predetermined abnormality process (S15). In step S15, the controller 21 stops the DC power supply 31 to stop driving the laser light source 11, and further notifies the external device of the abnormality of the switch element 34 via the communication part 26. Accordingly, the controller 21 ends the process in FIG. 7A.

FIG. 7B is a flowchart showing another process of failure detection based on a monitoring signal.

In the flowchart in FIG. 7B, steps S12 and S13 in the flowchart in FIG. 7A are replaced by steps S21 and S22. The process in each step other than steps S21 and S22 in FIG. 7B is the same as in the corresponding step in FIG. 7A.

When the controller 21 extracts a waveform from the monitoring signal (S11), the controller 21 acquires the period T2 between the previous waveform extracted by the immediately previous process in FIG. 7B and the waveform extracted this time (S21). For example, the controller 21 acquires the time difference between the timings when these waveforms exceed the same voltage level, as the period T2. Then, the controller 21 determines whether or not the acquired period T2 is appropriate with respect to the period T1 of pulsed light emission (S22).

Specifically, when the period T2 acquired in step S21 and the period T1 of pulsed light emission match within an acceptable error range, the controller 21 determines that the period T2 acquired this time is appropriate. On the other hand, when the period T2 acquired in step S21 and the period T1 of pulsed light emission differ from each other beyond the acceptable error range, the controller 21 determines that the period T2 acquired this time is not appropriate.

When the period T2 acquired in step S21 is appropriate (S22: YES), the controller 21 determines that no failure has occurred in the switch element 34, and ends the process. In this case, the controller 21 executes the process from step S11 in FIG. 7B again, and executes the same process as above for the next waveform of the monitoring signal.

On the other hand, when the period T2 acquired in step S21 is not appropriate (S22: NO), the controller 21 determines that a failure has occurred in the switch element 34 (S14), and executes a predetermined abnormality process (S15). The process executed in step S15 is the same as in the case of FIG. 7A.

As described above, in each of the processes in FIG. 7A or FIG. 7B, the predetermined abnormality process is executed when, on the basis of the fact that the waveform generated in the monitoring signal is not appropriate, it is detected that a failure has occurred in the switch element 34. Accordingly, abnormal operation of the light emission device 2 can be stopped promptly.

As the abnormality detection process using the monitoring signal, either one of the processes in FIG. 7A and FIG. 7B may be performed, or both of these processes may be performed. However, in the process in FIG. 7B, for example, when a failure of the switch element 34 occurs immediately before the timing of start of pulsed light emission, the period T2 in step S21 and the period T1 of pulsed light emission substantially match. Therefore, in such a case, it is difficult to properly detect the failure of the switch element 34 by the process in FIG. 7B. On the other hand, in the process in FIG. 7A, even in such as case, a difference ΔV equal to or greater than the threshold occurs between the peak voltage acquired in step S12 and the reference voltage, and thus a failure of the switch element 34 can be properly detected. Therefore, by using the process in FIG. 7A, a failure of the switch element 34 can be detected more accurately.

However, the abnormality detection process using the monitoring signal is not limited to the processes in FIG. 7A and FIG. 7B.

For example, the presence/absence of a failure of the switch element 34 may be detected on the basis of the degree of matching between the locus of a reference waveform generated in the monitoring signal during normal operation and the locus of the waveform extracted in step S11. In this case, the controller 21 (failure detection part 21a) stores therein in advance the locus (reference locus) of the reference waveform generated in the monitoring signal when the switch element 34 is made normally conductive. Then, the controller 21 calculates the degree of matching between the locus of the extraction waveform extracted in step S11 and the reference locus stored therein in advance, and determines whether or not the extraction waveform is appropriate, on the basis of whether or not the calculated degree of matching is equal to or greater than a predetermined threshold (e.g., 70%).

When the degree of matching is equal to or greater than the threshold, the controller 21 determines that no failure has occurred in the switch element 34, and when the degree of matching is less than the threshold, the controller 21 determines that a failure has occurred in the switch element 34. The process in the case where it is determined that a failure has occurred in the switch element 34 is the same as in steps S15 in FIG. 7A and FIG. 7B. With this process, a failure of the switch element 34 can also be properly detected as in the processes in FIG. 7A and FIG. 7B.

### Effects of Embodiment

According to the above embodiment, the following effects can be achieved.

As shown in FIG. 2, the light emission device 2 includes the monitoring circuit 40 which monitors temporal change in the voltage of the electric storage element 33, and thus can detect a failure of the switch element 34 during operation of the laser light source 11. That is, when a failure such as a short circuit occurs in the switch element 34, the voltage waveform (temporal change in the voltage) of the electric storage element 33 generated by the discharge of the electric storage element 33 changes from the state during normal operation as shown in FIG. 5C. Therefore, during operation of the laser light source 11, by monitoring temporal change in the voltage of the electric storage element 33 by the monitoring circuit 40, a failure of the switch element 34 can be detected at any time. Accordingly, an abnormality based on a failure of the switch element 34 can be detected in real time.

As shown in FIG. 2, the monitoring circuit 40 includes the capacitor 41 and is AC connected to the electric storage element 33 via the capacitor 41. Accordingly, the current from the electric storage element 33 is inhibited from flowing to the monitoring circuit 40 when the switch element 34 is set to a conductive state. Therefore, the current from the electric storage element 33 can be caused to properly flow to the main circuitry on the laser light source 11 side, thereby allowing the laser light source 11 to properly emit pulsed light.

As shown in FIG. 2, the monitoring circuit 40 includes the resistors 42 and 43 (voltage-dividing resistor 51) connected between the capacitor 41 and the ground. Accordingly, by adjusting the resistance values of the resistors 42 and 43, the voltage level of the monitoring signal can be set to a voltage level suitable for the circuitry (controller 21, etc.) on the subsequent stage side. Therefore, the process using the monitoring signal can be smoothly performed in the circuitry on the subsequent stage side.

As shown in FIG. 2, the monitoring circuit 40 includes the polarity inversion circuit 52 which inverts the polarity of the voltage divided by the resistors 42 and 43 (voltage-dividing resistor 51). Accordingly, the monitoring signal having a positive polarity can be outputted to the circuitry on the subsequent stage side. Therefore, the process using the monitoring signal can be smoothly performed in the circuitry on the subsequent stage side.

As shown in FIG. 1 and FIG. 6, the light emission device 2 includes the failure detection part 21a which detects a failure of the switch element 34 on the basis of the monitoring signal generated by the monitoring circuit 40. Accordingly, a failure of the switch element 34 can be detected using the monitoring signal, and a response to occurrence of a failure can be executed smoothly. Therefore, an abnormality of light emission of the light emission device 2 can be properly prevented.

As shown in FIG. 7A, the controller 21 (failure detection part 21a) detects a failure of the switch element 34 on the basis of the difference ΔV (see FIG. 5D) between the reference voltage corresponding to the peak voltage of the monitoring signal generated by the drive of the switch element 34 when the switch element 34 is normal and the peak voltage of the monitoring signal acquired in step S12 (S12 to S14). Accordingly, as described above with reference to FIG. 5D, a failure of the switch element 34 can be properly detected using the monitoring signal.

As shown in FIG. 7B, the controller 21 (failure detection part 21a) detects a failure of the switch element 34 on the basis of the period T2 (see FIG. 5D) of the waveform generated in the monitoring signal in response to the discharge of the electric storage element 33 (S21, S22, S14). Accordingly, as described above with reference to FIG. 5D, a failure of the switch element 34 can be properly detected using the monitoring signal.

As shown in FIG. 1, the distance measurement device 1 includes the light emission device 2 (see FIG. 2) including the monitoring circuit 40. Therefore, a failure of the switch element 34 can be detected at any time during operation of the laser light source 11, and control for suppressing an abnormality of pulsed light emission as shown in FIG. 7A and FIG. 7B can be performed on the basis of the detection result. Therefore, the reliability of the distance measurement device 1 can be increased.

### Modifications

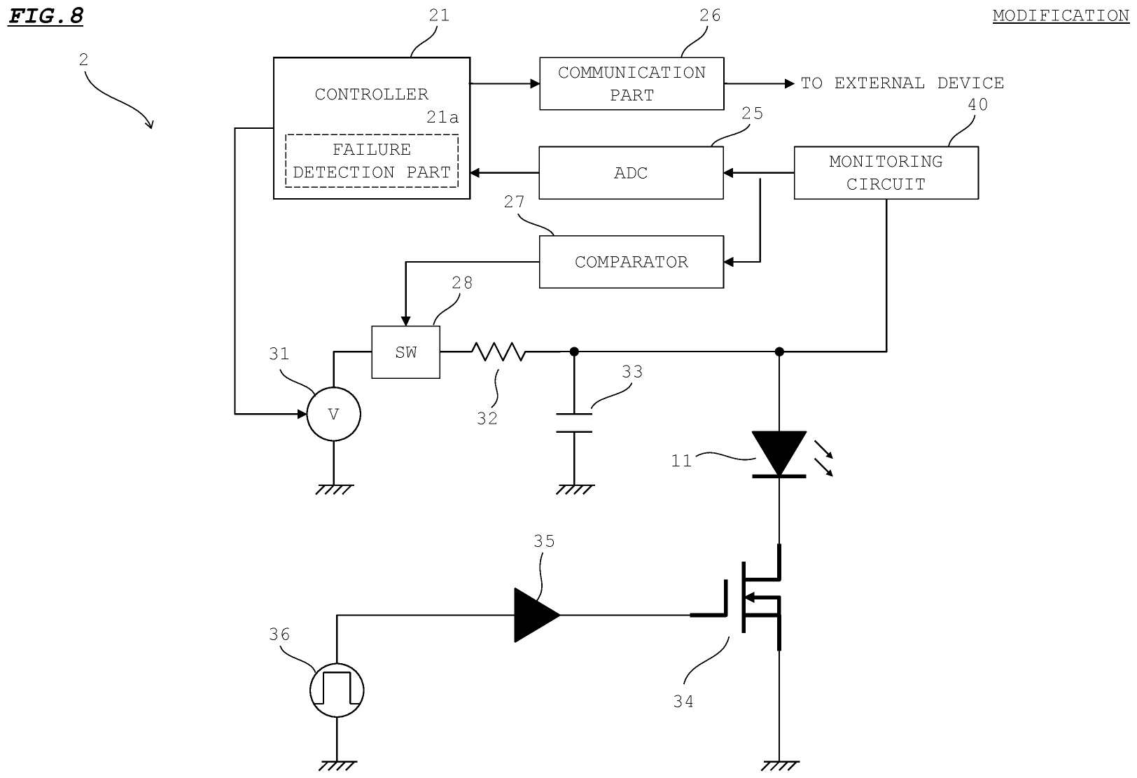

The configuration of the circuitry shown in FIG. 6 may be modified as shown in FIG. 8.

In the configuration in FIG. 8, a comparator 27 and a switch 28 are added to the configuration in FIG. 6. The comparator 27 is composed of an analog circuit, extracts the peak voltage of a waveform that changes beyond a predetermined noise level, from the monitoring signal (analog signal) inputted from the monitoring circuit 40, and compares the difference between the extracted peak voltage and a reference voltage with a threshold. When this difference exceeds the threshold, the comparator 27 outputs a detection signal to the switch 28. The reference voltage and the threshold are set to be the same as in step S13 in FIG. 7A.

When the detection signal is outputted from the comparator 27, the switch 28 is opened and the DC voltage of the DC power supply 31 is blocked with respect to the resistor 32. Accordingly, the voltage supply to the electric storage element 33 is blocked, so that abnormal light emission of the laser light source 11 is suppressed.

In this configuration, since the switch 28 is opened by analog processing, when a failure occurs in the switch element 34, the supply of the DC power supply 31 to the electric storage element 33 can be stopped more quickly than in the configuration in FIG. 6. Therefore, the laser light source 11 can be more reliably prevented from emitting light in an inappropriate light-emitting state.

In the configuration in FIG. 8, together with the function of the failure detection part 21a provided in the controller 21, the comparator 27 constitutes a failure detection part.

In the modification, the position at which the switch 28 is placed is not limited to the position in FIG. 8, and may be another position as long as it is possible to stop light emission of the laser light source 11 when a failure occurs in the switch element 34. For example, the switch 28 may be placed immediately after the resistor 32 (between the resistor 32 and the electric storage element 33).

### Other Modifications

The configurations of the light emission device 2 and the distance measurement device 1 can be modified in various ways other than the configurations shown in the embodiment and the modification described above.

For example, in the embodiment and the modification described above, the electric storage element 33, the laser light source 11, and the switch element 34 are placed in this order along the direction in which the drive current flows, but the order of placement is not limited thereto.

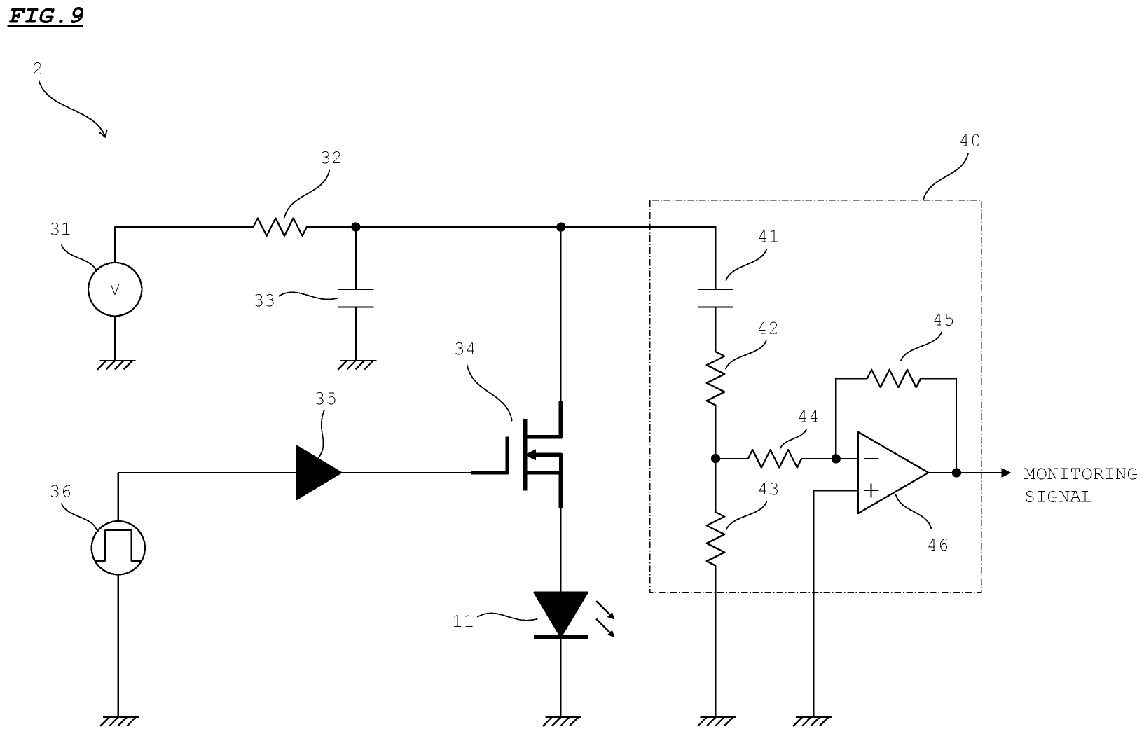

For example, as shown in FIG. 9, the electric storage element 33, the switch element 34, and the laser light source 11 may be placed in this order along the direction in which the drive current flows. In this case as well, as in the above embodiment, by monitoring temporal change in the voltage of the electric storage element 33 by the monitoring circuit 40, a failure of the switch element 34 can be detected.

In the above embodiment, the light emission device 2 is installed in the so-called flash type distance measurement device 1 which simultaneously emits light to the entire distance measurement region A10. However, the present invention is not limited thereto, and the light emission device 2 may be installed in a distance measurement device of a type that performs scanning with a line beam in a short side direction or a distance measurement device of a type that performs scanning with a point beam in a two-dimensional direction.

In addition to the above, various modifications can be made as appropriate to the embodiment of the present invention, without departing from the scope of the technological idea defined by the claims.

What is claimed is:

1. A light emission device comprising:
a laser light source;
an electric storage element for supplying a drive current to the laser light source;
a switch element connected in series to the laser light source; and
a monitoring circuit configured to monitor temporal change in a voltage of the electric storage element.

2. The light emission device according to claim 1, wherein the monitoring circuit includes a capacitor and is AC connected to the electric storage element via the capacitor.

3. The light emission device according to claim 2, wherein the monitoring circuit includes a voltage-dividing resistor connected between the capacitor and a ground.

4. The light emission device according to claim 3, wherein the monitoring circuit includes a polarity inversion circuit configured to invert a polarity of a voltage divided by the voltage-dividing resistor.

5. The light emission device according to claim 1, further comprising a failure detection part configured to detect a failure of the switch element on the basis of a monitoring signal generated by the monitoring circuit.

6. The light emission device according to claim 5, wherein the failure detection part detects a failure of the switch element on the basis of a difference between a reference voltage corresponding to a peak voltage of the monitoring signal generated by drive of the switch element when the switch element is normal and a peak voltage of the monitoring signal.

7. The light emission device according to claim 5, wherein the failure detection part detects a failure of the switch element on the basis of a period of a waveform generated in the monitoring signal in response to discharge of the electric storage element.

8. A distance measurement device comprising:
a light emission device;
a projection optical system configured to project pulsed light emitted from the light emission device, to a target region; and
a light receiver configured to receive reflected light, from an object, of the pulsed light, wherein
the light emission device includes
a laser light source,
an electric storage element for supplying a drive current to the laser light source,
a switch element connected in series to the laser light source, and
a monitoring circuit configured to monitor temporal change in a voltage of the electric storage element.

9. The distance measurement device according to claim 8, wherein the monitoring circuit includes a capacitor and is AC connected to the electric storage element via the capacitor.

10. The distance measurement device according to claim 9, wherein the monitoring circuit includes a voltage-dividing resistor connected between the capacitor and a ground.

11. The distance measurement device according to claim wherein the monitoring circuit includes a polarity inversion circuit configured to invert a polarity of a voltage divided by the voltage-dividing resistor.

12. The distance measurement device according to claim 8, wherein the light emission device further includes a failure detection part configured to detect a failure of the switch element on the basis of a monitoring signal generated by the monitoring circuit.

13. The distance measurement device according to claim 12, wherein the failure detection part detects a failure of the switch element on the basis of a difference between a reference voltage corresponding to a peak voltage of the monitoring signal generated by drive of the switch element when the switch element is normal and a peak voltage of the monitoring signal.

14. The distance measurement device according to claim 12, wherein the failure detection part detects a failure of the switch element on the basis of a period of a waveform generated in the monitoring signal in response to discharge of the electric storage element.
